(19) United States
(12) Patent Application Publication
(10) Pub. No.: US 2010/0079168 A1
(43) Pub. Date: Apr. 1, 2010

(54) SEMICONDUCTOR INTEGRATED CIRCUIT AND LAYOUT METHOD

(76) Inventor: Masahisa Tashiro, Tokyo (JP)

Correspondence Address: TAFT, STETTINIUS & HOLLISTER LLP, SUITE 1800, 425 WALNUT STREET, CINCINNATI, OH, 45202-3957, US

(21) Appl. No.: 12/562,780

(22) Filed: Sep. 18, 2009

(30) Foreign Application Priority Data
Sep. 30, 2008 (JP) 2008-254711

(51) Int. Cl. H03K 19/00; G06F 17/50; H03K 19/20

(52) U.S. Cl. 326/93; 716/12; 326/104; 326/101

(57) ABSTRACT

A semiconductor integrated circuit has a scan chain with a scan clock signal line for clocking scan flip-flops and a scan test signal line for transferring scanning data into and out of the scan flip-flops. Part of the scan test signal line is routed adjacently parallel to the scan clock signal line to shield the scan clock signal line from electrical noise during normal operation, when the scan test signal line is held at a fixed potential. Separate shield lines are used to shield parts of the scan clock signal line not shielded by the scan test signal line. Use of a combination of shield lines and the scan test signal line to shield the scan clock signal line saves space and conserves routing resources.

### CROSS-REFERENCE TO RELATED APPLICATIONS

This application claims priority under 35 U.S.C. §119 to Japanese Patent Application Serial No. JP2008-254711 filed on Sep. 30, 2008, the disclosure of which is hereby incorporated by reference.

### RELATED ART

1. Field of the Invention

The present disclosure relates to a semiconductor integrated circuit, more particularly to the layout of a semiconductor integrated circuit with a shielded scan clock signal line.

2. Brief Discussion of Related Art

Conventional semiconductor integrated circuits with built-in test features typically include a plurality of flip-flop circuits 121, 122, . . . connected by a scan test signal line 42 to form a scan shift register or scan chain as shown in FIG. 1. Additional logic circuits (NAND gates) 141, 142, . . . are inserted in the scan chain to hold the scan test signals constant during normal operation, so that power will not be consumed by needless switching of transistors in the flip-flop circuits in response to changes in the logic levels of the scan test signals.

The dimensions and spacing of the signal lines in semiconductor integrated circuits have become so small that crosstalk between adjacent signal lines poses significant problems, particularly when one of the signal lines is a clock signal line. In order to prevent such crosstalk, the scan clock signal line 22 in FIG. 1 is shielded by adjacent shield lines 24, indicated by dotted lines. The shield lines 24 do not supply power or carry signals; they are simply held at a fixed potential to prevent electrical noise from reaching the clock input terminals CK of the flip-flop circuits 121, 122 via the scan clock signal line 22.

Although the shield lines 24 and the scan test signal line 42 in FIG. 1 carry no signals during normal operation, they take up space in the layout of the semiconductor integrated circuit 40 and require considerable use of routing resources (space available for the routing of signal lines), raising the chip cost of the integrated circuit 40.

A scan clock signal line 22 may also be shielded as shown in FIG. 2, simply by leaving a wide region 30 around it free of other signal lines. Setting aside this type of shielding region 30, however, reduces available routing resources and increases the chip area, raising the chip cost of the integrated circuit 41.

The shielding of clock signal lines (not shown in FIGS. 1 and 2) that distribute clock signals to the combinatorial circuit blocks 161, 162 of a semiconductor integrated circuit poses similar problems. A known shielding method that does not require the use of special shield lines or a special shielding region is to surround the clock signal lines with signal lines carrying signals that do not change state during normal operation. In Japanese Patent Application Publication No. H10-242282, Anbutsu proposes the use of scan signal lines, or scan signal lines and reset signal lines, as shield lines. In Japanese Patent Application Publication No. H11-274308, Shihara also proposes the use of scan signal lines as shield lines. In Japanese Patent Application Publication No. 2001-24172, Takahashi proposes the use of a scan signal line as a shield line on one side of the clock signal line and a power line (VDD or ground) as a shield line on the other side of the clock signal line.

These three schemes, which shield clock signal lines by using scan signal lines as shield lines, share the common disadvantage that the scan signal lines must often be routed on paths that are much longer than necessary. A further problem, during scan tests, is interference between the scan signal lines and the clock signal lines they shield.

### INTRODUCTION TO THE INVENTION

An object of the present disclosure is to save space and conserve routing resources in a semiconductor integrated circuit having a shielded scan clock signal line.

The disclosure concerns a semiconductor integrated circuit that has a plurality of flip-flop circuits connected in a scan chain by a scan test signal line, a plurality of logic circuits inserted into the scan chain to hold the scan test signal line at a fixed logic level during normal operation, and a clock signal line for supplying a clock signal to the flip-flop circuits. The disclosure also concerns methods of laying out this type of semiconductor integrated circuit.

According to one aspect of the disclosure, the semiconductor integrated circuit includes at least one shield line disposed adjacent and parallel to the clock signal line. At least one part of the scan test signal line is also disposed adjacent and parallel to the clock signal line. The combination of the at least one shield line and the at least one part of the scan test signal line forms a shielding structure that shields all parts of the clock signal line on both sides. When the semiconductor integrated circuit is laid out, first the flip-flop circuits are laid out, then the logic circuits and the clock signal line are laid out, and then the shielding structure is laid out.

According to another aspect of the disclosure, the clock signal line and at least part of the scan test signal line connected between the logic circuits and the data input terminals of the flip-flop circuits are disposed in a shielding region that shields the clock signal line from electrical interference by surrounding the clock signal line with an area that is free of other signal lines, except for the scan test signal line and the clock signal line itself. When the semiconductor integrated circuit is laid out, first the flip-flop circuits are laid out, then the logic circuits and the clock signal line are laid out, then the shielding region is laid out, and then the scan test signal line is laid out.

By using part of the scan test signal line to shield the clock signal line, or by placing part of the scan test signal line in the shielding region, space is saved and routing resources are conserved.

### BRIEF DESCRIPTION OF THE DRAWINGS

In the attached drawings:

FIG. 1 is a block diagram schematically showing the structure of an exemplary conventional semiconductor integrated circuit with shield lines;

FIG. 2 is a block diagram schematically showing the structure of an exemplary conventional semiconductor integrated circuit with a shielding region;

FIG. 3 is a block diagram schematically showing the structure of an exemplary semiconductor integrated circuit according to a first embodiment of the disclosure;

FIG. 4 is a block diagram schematically showing the structure of another exemplary semiconductor integrated circuit according to the first embodiment of the disclosure;

FIG. 5 is a flowchart illustrating an exemplary conventional semiconductor integrated circuit layout process;

FIG. 6 is a block diagram schematically showing the structure of an exemplary semiconductor integrated circuit layout apparatus used in the first embodiment of the disclosure;

FIG. 7 is a flowchart illustrating an exemplary semiconductor integrated circuit layout process according to the first embodiment of the disclosure;

FIG. 8 is a block diagram schematically showing the structure of an exemplary semiconductor integrated circuit according to a second embodiment of the disclosure; and

FIG. 9 is a flowchart illustrating an exemplary semiconductor integrated circuit layout process according to the second embodiment of the disclosure.

### DETAILED DESCRIPTION

The exemplary embodiments of the present disclosure are described and illustrated below to encompass a semiconductor integrated circuit, more particularly to the layout of a semiconductor integrated circuit with a shielded scan clock signal line. Of course, it will be apparent to those of ordinary skill in the art that the preferred embodiments discussed below are exemplary in nature and may be reconfigured without departing from the scope and spirit of the present invention. However, for clarity and precision, the exemplary embodiments as discussed below may include optional steps, methods, and features that one of ordinary skill should recognize as not being a requisite to fall within the scope of the present invention.

### First Embodiment

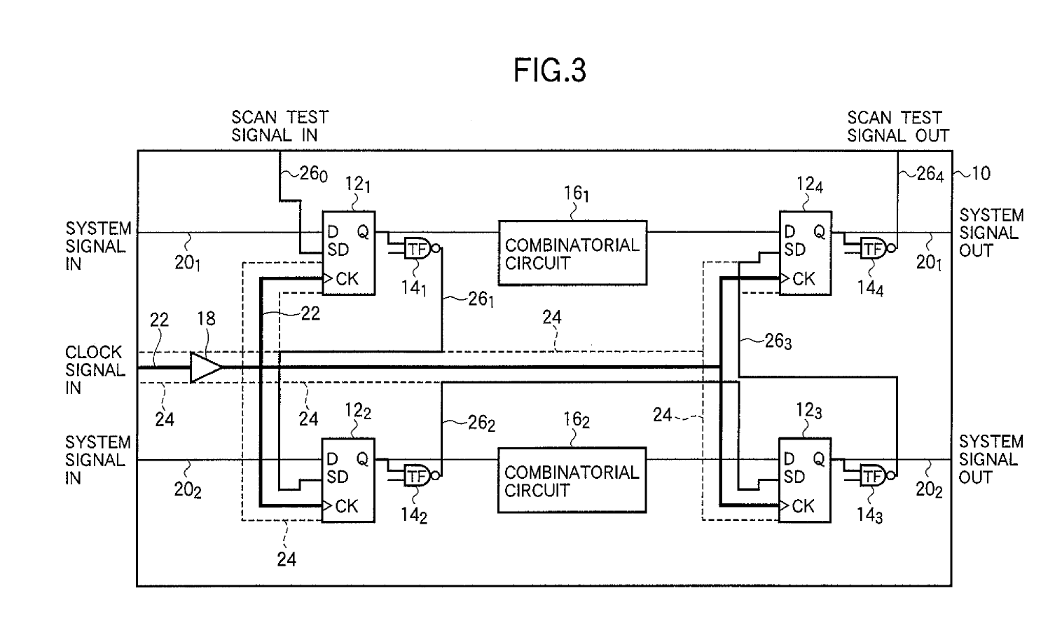

FIG. 3 is a plan view of a semiconductor integrated circuit 10 with a multilayer signal line structure, showing only elements relevant to the first embodiment. These elements include four flip-flop circuits 121 to 124, four NAND circuits 141 to 144, two combinatorial circuit blocks 161, 162, and a clock driver circuit 18.

In the semiconductor integrated circuit 10, a system signal line 201 is routed from a system signal input terminal to a system signal output terminal via the data input terminal D and data output terminal Q of flip-flop circuit 121, combinatorial circuit block 161, and the data input terminal D and data output terminal Q of flip-flop circuit 124. During normal operation, a system signal is Supplied from an external device through the system signal input terminal and flip-flop circuit 121 to combinatorial circuit block 161, combinatorial circuit block 161 performs a corresponding operation, and a resulting signal is output through flip-flop circuit 124 and the system signal output terminal to an external device.

Similarly, a system signal line 202 is routed from another system signal input terminal to another system signal output terminal via the data input terminal D and data output terminal Q of flip-flop circuit 122, the combinatorial circuit block 162, and the data input terminal D and data output terminal Q of flip-flop circuit 123. During normal operation, another system signal is similarly processed by these circuits.

A scan test signal line 260 is routed from a scan test signal input terminal to the scan data input terminal SD of flip-flop circuit 121. Another scan test signal line 261 is branched from the data output terminal Q of flip-flop circuit 121 through NAND circuit 141 and is connected to the scan data input terminal SD of flip-flop circuit 122. Similarly, a scan test signal line 262 is branched from the data output terminal Q of flip-flop circuit 122 through NAND circuit 142 to the scan data input terminal SD of flip-flop circuit 123, a scan test signal line 263 is branched from the data output terminal Q of the flip-flop circuit 123 through NAND circuit 143 to the scan data input terminal SD of flip-flop circuit 124, and a scan test signal line 264 is branched from the data output terminal Q of flip-flop circuit 124 through NAND circuit 144 to a scan test signal output terminal. Scan test signal lines 260 to 264 will be referred to collectively as the scan test signal line 260-4.

The scan test signal line 260-4, the flip-flop circuits 121 to 124, and the NAND circuits 141 to 144 form a scan path or scan chain. During a scan test, scan test data are input from the scan test signal input terminal and scan output data are obtained from the scan signal output terminal.

The NAND circuits 141 to 144 hold the signal levels on scan test signal lines 261 to 264 at a constant level during normal operation by blocking the data output from the data output terminals of the flip-flop circuits 121 to 124. The NAND circuits 141 to 144 have one input terminal that receives the signal output from the data output terminal Q of the corresponding flip-flop circuit 12i (i=1, 2, 3, or 4) and another input terminal that receives a test enable (TE) control signal. During normal operation, the test enable control signal is held at the low logic level (the ground level, GND) and the NAND circuits 141 to 144 hold the scan test signal lines 261 to 264 at the high logic level (the power supply level, VDD).

In a variation of this scheme, NOR circuits are used instead of NAND circuits 141 to 144. During normal operation the test enable control signal is held at the VDD level and the scan signal lines 261 to 264 are held at the GND level.

In another variation, OR circuits are used instead of the NAND circuits 141 to 144, and during normal operation the test enable control signal and the scan signal lines 261 to 264 are both held at the VDD level.

In yet another variation, AND circuits are used instead of the NAND circuits 141 to 144, and during normal operation the test enable control signal and the scan signal lines 261 to 264 are both held at the GND level.

A scan clock signal line 22 is routed from a clock signal input terminal through the clock driver circuit 18 to the clock signal input terminals CK of the flip-flop circuits 121 to 124, to supply a clock signal to the flip-flop circuits 121 to 124.

A plurality of shield lines 24 are disposed adjacently parallel to parts of the scan clock signal line 22. The shield lines 24 are held at a fixed potential (e.g., VDD or GND) to prevent crosstalk between the scan clock signal line 22 and the system signal lines 201, 202, crosstalk between different parts of the scan clock signal line 22, and crosstalk between the scan clock signal line 22 and other signal lines (not shown).

Parts of scan test signal lines 261 to 263 are also disposed adjacently parallel to the scan clock signal line 22. During normal operation, since the scan test signal lines 261 to 263 are held at fixed levels (e.g., VDD or GND), they also shield the scan clock signal line 22 and prevent crosstalk.

All parts of the scan clock signal line 22 have either a shield line 24 or one of the scan test signal lines 261 to 263 running parallel to them on both sides. During normal operation, accordingly, the scan clock signal line 22 is completely shielded from the effects of crosstalk noise.

The distances between the shield lines 24 and the scan clock signal line 22 and the distances between the above parts of the scan test signal lines 261 to 263 and the scan clock signal line 22 need not all be equal, as long as the shield lines 24 and the parts of the scan test signal lines 261 to 263 are at such a distance from the scan clock signal line 22 that they provide an adequate shielding effect.

To reduce the necessary amount of shield line wiring, the scan clock signal line 22 is preferably shielded by adjacent scan test signal lines 261 to 263 as far as this can be done without greatly increasing the total length of the scan test signal line 260-4. The total length of the scan test signal line 260-4 is preferably optimized with respect to such factors as the scan test signal delay, routing complexity, and increase in chip cost.

During a scan test, the signal level on scan test signal lines 261 to 263 changes as scan test data are clocked into and out of the four flip-flop circuits 121 to 124, but the frequency of the clock signal on the scan clock signal line 22 during this operation is very low, so crosstalk between the scan clock signal line 22 and the adjacent parts of scan test signal lines 261 to 263 does not pose a problem.

During normal operation, the scan clock signal line 22 is completely shielded on both sides by the shield lines 24 and parts of the scan test signal lines 261 to 263 as described above, so crosstalk does not cause problems during normal operation either. At all times, the scan clock signal line 22 is substantially free of noise.

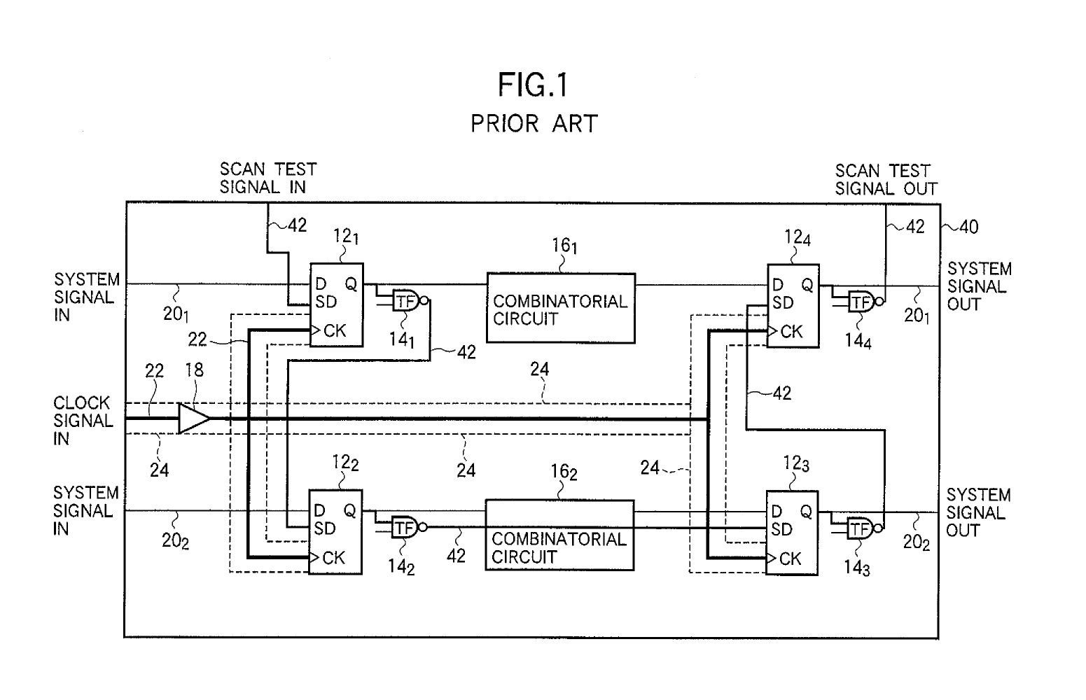

Since the scan test signal lines 261 to 263 in FIG. 3 replace substantial parts of the shield lines 24 in FIG. 1, the combination of the shield lines 24 and the scan test signal line 260-4 in FIG. 3 uses up fewer routing resources (available signal line space) than the combination of the shield lines 24 and the scan test signal line 42 in FIG. 1. The combination of the shield lines 24 and the scan test signal line 260-4 in FIG. 3 also uses up fewer routing resources than would be required if the scan clock signal line 22 were to be shielded entirely by the scan test signal line 260-4. Using the combination of the shield lines 24 and the scan test signal line 260-4 for scan clock shielding enables the chip cost to be reduced.

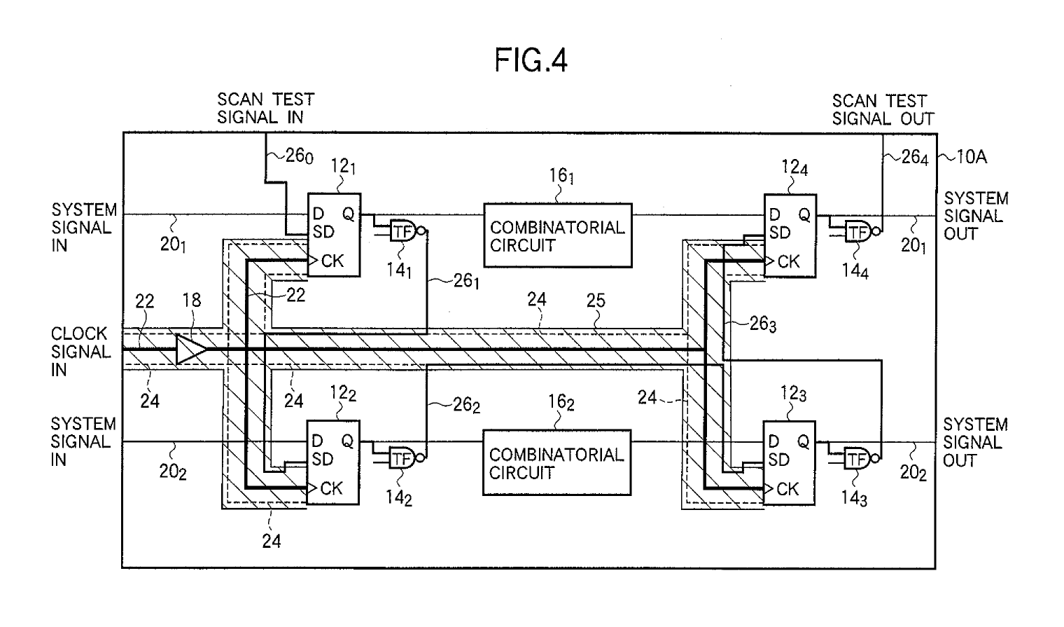

FIG. 4 shows another exemplary semiconductor integrated circuit according to the first embodiment. The difference between the semiconductor integrated circuit 10A in FIG. 4 and the semiconductor integrated circuit 10 in FIG. 3 is that in the semiconductor integrated circuit 10A in FIG. 4, a shield line layout region 25 is set aside for the shield lines 24. The dimensions of the shield line layout region 25, more specifically, the distance to which it extends from the scan clock signal line 22, are determined by shielding requirements, so that shield lines placed within the shield line layout region 25 can prevent interference between the clock signal on the scan clock signal line 22 and signals on signal lines outside the shield line 24.

Parts of the scan test signal lines 261 to 263 are disposed inside the shield line layout region 25, paralleling the scan clock signal line 22, to shield parts of the scan clock signal line 22. The shield lines 24 shield the remaining parts of the scan clock signal line 22.

Next, a semiconductor integrated circuit layout method will be described.

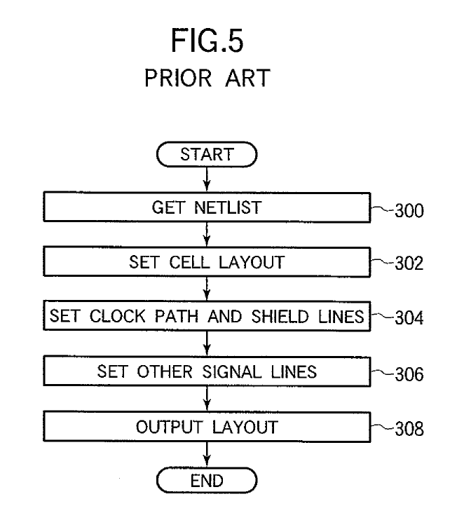

First, for reference, the conventional flow of the layout process for a typical semiconductor integrated circuit (the semiconductor integrated circuit 40 in FIG. 1) will be described with reference to FIG. 5. First a netlist is obtained in step 300. Next, semiconductor cells, including scan flip-flop circuits, are laid out according to the netlist in step 302. Next, the scan clock signal line 22 and the shield lines 24 are laid out (routed) in step 304. Next, other signal lines are laid out (routed) in step 306. Finally, the completed layout is output in step 308.

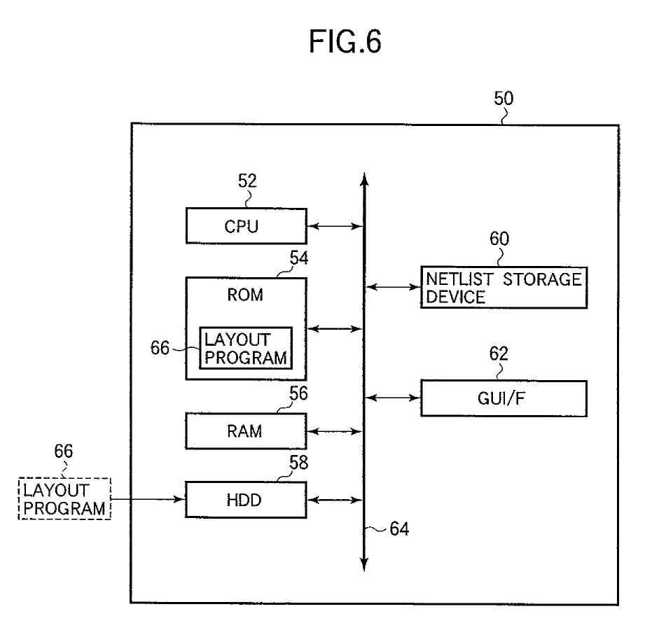

Next, a method of laying out the semiconductor integrated circuit 10 in the first embodiment will be described. The method is carried out using the exemplary semiconductor integrated circuit layout apparatus 50 shown in block diagram form in FIG. 6.

The semiconductor integrated circuit layout apparatus 50 comprises a central processing unit (CPU) 52, a read-only memory (ROM) 54, a random access memory (RAM) 56, a hard disk drive (HDD) 58, a netlist storage device 60, and a graphic user interface (GUI/F) 62. The semiconductor integrated circuit layout apparatus 50 may be a computing device such as a personal computer or an engineering workstation.

The CPU 52 controls the entire semiconductor integrated circuit layout apparatus 50 and executes the layout process by executing a layout program 66 stored in the ROM 54 or the hard disk drive 58. The layout program 66 may also be stored in removable media (not shown), such as a compact disc ROM (CD-ROM), a digital versatile disc ROM (DVD-ROM), or a removable semiconductor memory, and may be installed by being copied onto, for example, the hard disk drive 58, so that the layout program 66 can be read and executed by the CPU 52.

The ROM 54 also stores other programs, parameters, and data used by the CPU 52. The RAM 56 is used as, for example, a work area when the CPU 52 executes the layout program 66 and other programs.

The netlist storage device 60 stores the netlist for the layout of the semiconductor integrated circuit 10. The netlist specifies the semiconductor circuit cells making up the semiconductor integrated circuit 10, and defines their input and output signals and logical interconnections. In this embodiment, the netlist is input ahead of time by the user and stored in the netlist storage device 60.

The graphic user interface 62 is used by the user to input, for example, the netlist and instructions associated with the layout of the semiconductor integrated circuit 10, and is used to output, for example, information about the layout and the completed semiconductor integrated circuit 10. The graphic user interface 62 may include several separate devices, such as a touch panel, a display, a mouse, and a keyboard. Output may also be performed by output apparatus such as a printer.

The CPU 52, ROM 54, RAM 56, hard disk drive 58, netlist storage device 60, and graphic user interface 62 are communicably interconnected by a bus 64 including control, data, and address signal lines.

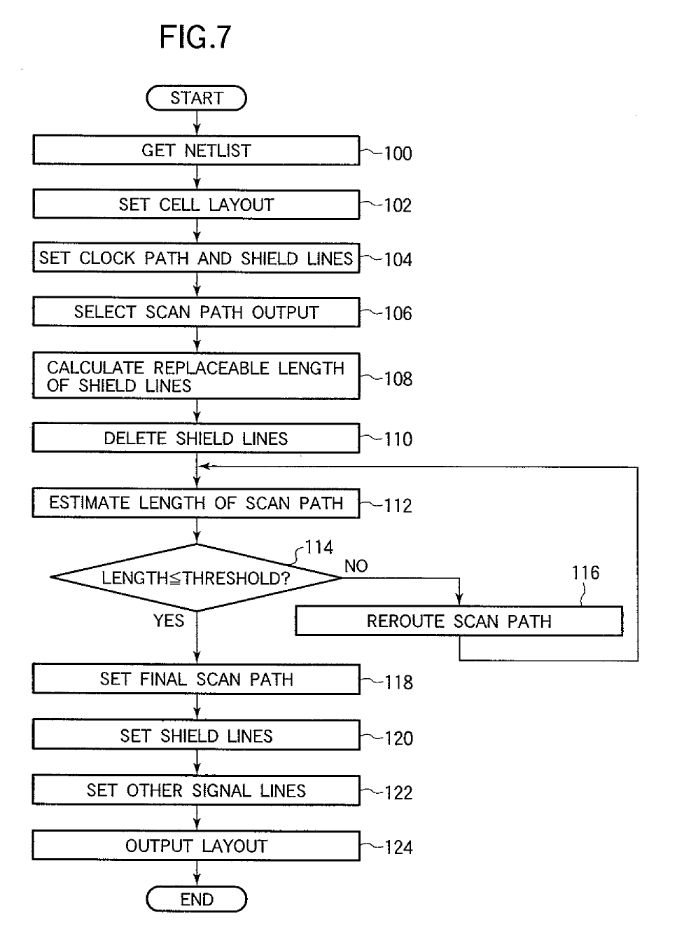

Next, the layout processing (layout method) of the first embodiment will be described with reference to the exemplary semiconductor integrated circuit layout process flowchart in FIG. 7.

Step 100 is a netlist acquisition step, in which a netlist is obtained from the netlist storage device 60.

Step 102 is a cell layout step, in which semiconductor cells including the flip-flop circuits 121 to 124, NAND circuits 141 to 144, and combinatorial circuit blocks 161, 162 are laid out according to the netlist.

Step 104 is a clock path and shield line routing step, in which the scan clock signal line 22 and shield lines 24 are routed. In this step, the shield lines 24 are routed so as to shield the scan clock signal line 22 on both sides for its entire length.

Step 106 is a scan path output selection step, in which scan path output is selected. When scan path output is selected, a scan path can be found from the logical interconnections defined in the netlist by tracing paths from the data output terminals Q of the four flip-flop circuits 121 to 124 (through the NAND circuits 141 to 144) to the data input terminals SD of the four flip-flop circuits 121 to 124. For example, a path from the data output terminal Q of flip-flop circuit 121 (the path from the output terminal of NAND circuit 141) to the scan data input terminal of the flip-flop circuit 122 may be selected instead of the path from flip-flop circuit 121 to combinatorial circuit block 161, thereby defining scan test signal line 261. Scan test signal lines 262 and 263 may then be similarly selected to complete the scan path from flip-flop circuit 121 to flip-flop circuit 124. Paths for the test enable control signals and flip-flop control signals (not shown) may also be selected at this point.

Step 108 is a resource calculation step in which the total usage of routing resources by the replaceable parts of the shield lines 24 is calculated. More specifically, the total length of the routing resources that were assigned to the shield lines 24 in step 104 but could be replaced by the scan test signal line 260-4 if the maximum possible use of the scan test signal line 260-4 were to be made to shield the scan clock signal line 22 is calculated. This step can be carried out by redefining the space occupied by the shield lines 24 as space available for routing the scan test signal lines 261 to 263, tentatively routing the scan test signal lines 261 to 263 to make maximum possible use of this available space, and calculating the total length of the scan test signal lines 261 to 263 within this space.

When a shield line layout region 25 is provided as in the semiconductor integrated circuit 10A shown in FIG. 4, the shield line layout region 25 may be defined as the shielding space made available for routing the scan test signal line 260-4.

The total length calculated in step 108 will generally be approximately equal to the total length of the scan clock signal line 22.

Step 110 is a shield line deletion step, in which the shield lines 24 are deleted from the layout of the semiconductor integrated circuit 10. This step 110 may be executed automatically by the layout generation program.

Step 112 is a scan path routing resource estimation step, in which the total length of scan test signal lines 261 to 263 as currently routed is calculated. The first time step 112 is carried out, the scan test signal lines 261 to 263 are routed to make maximum use of the available shielding space, as in step 108. The calculated length includes birth the parts of the scan test signal lines 261 to 263 that replace shield lines 24 and other parts of the scan test signal lines 261 to 263.

Step 114 is a resource comparison step, in which the total length of scan test signal lines 261 to 263 calculated in step 112 is compared with the calculated total length of the replaceable part of the shield wiring calculated in step 108. More precisely, the total length calculated in step 112 is compared with a threshold value derived from the total length calculated in step 108, such as a threshold value equal to 1.2 times the total length calculated in step 108. If the total length calculated in step 112 exceeds the threshold value, the layout process proceeds to step 116; otherwise, the layout process proceeds to step 118.

The threshold value is not limited to 1.2 times the total length calculated in step 108. The threshold value should be selected in consideration of factors such as the scan test signal delay, routing complexity, and increase in chip size and cost, as noted above. Generally speaking, a threshold value that is a little larger than the total length calculated in step 108 is preferable.

Step 116 is a scan reordering step in which the scan test signal lines 261 to 263 are rerouted by, for example, reducing the amount to which these scan test signal lines are used for shielding, or changing the order of the flip-flop circuits 121 to 124 in the scan chain, so as to shorten the total length of the scan test signal lines 261 to 263. The process then returns to step 112.

Steps 112 to 116 are iterated until the total length of scan test signal lines 261 to 263 is equal to or less than the threshold value in step 114. The process then proceeds to step 118.

In step 118 the layout of the scan test signal lines 261 to 263 is finalized as the layout that satisfied the threshold condition in step 114.

Step 120 is a shield routing step in which the parts of the shield lines 24 were not replaced by test signal lines in the final layout of the scan test signal lines 261 to 263 are restored to the routes assigned to them in step 104.

Step 122 is a routing step for signal lines that have not yet been laid out, such as scan test signal lines 260 and 264 and the system signal lines 201, 202 in FIG. 3.

Step 124 is a layout output step, in which the graphic user interface 62 outputs the cell layout obtained in step 102, the clock path layout obtained in step 104, and the routing layouts obtained in steps 118, 120, and 122. The semiconductor integrated circuit may be fabricated according to the layout output in step 124.

As described above, according to the semiconductor integrated circuit layout method of the first embodiment (the exemplary processing flow in FIG. 7), first the scan clock signal line 22 is shielded with shield lines 24; then the space occupied by the shield lines 24 is made available as a routing resource for the scan test signal lines 261 to 263, and in the final layout, the scan clock signal line 22 is shielded by a combination of shield lines 24 and the scan test signal lines 261 to 263, both of which are held at a constant signal level during normal operation. This enables the scan clock signal line 22 to be shielded from crosstalk noise in an economical way, conserving routing resources and reducing the chip cost of the semiconductor integrated circuit 10.

In a further variation of the first embodiment, to simplify step 108, the threshold length with which the total length of scan test signal lines 261 to 263 is compared is derived from the total length of the clock signal line 22 instead of from the total length of the replaceable shield lines 24.

In a still further variation of the first embodiment, the entire scan test signal line 260-264 is routed and rerouted in steps 108 and 116, and the total length of the entire scan test signal line 260-264 is compared with a threshold value derived from the total length of the clock signal line 22.

### Second Embodiment

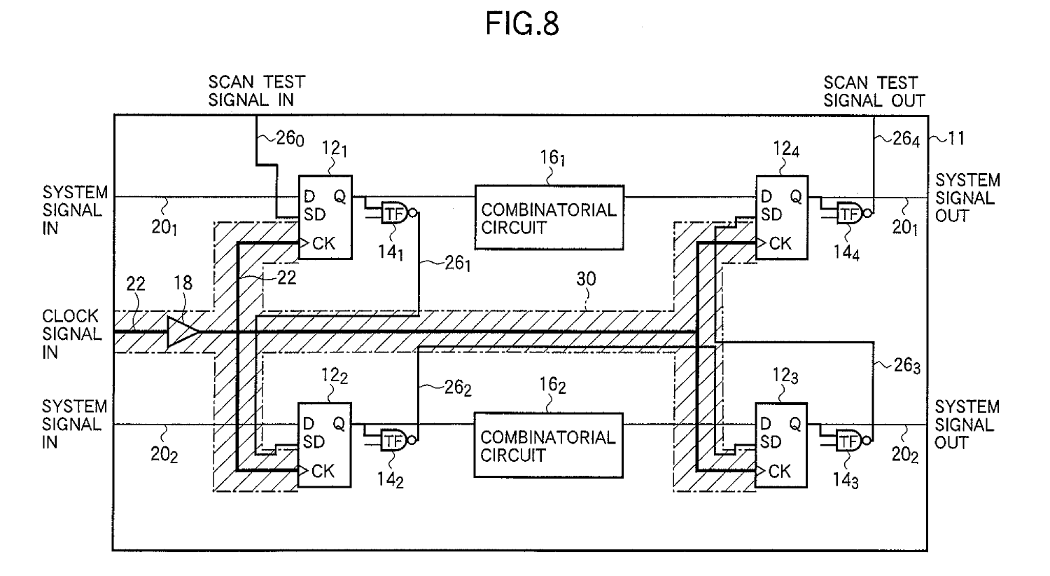

Referring to FIG. 8, the semiconductor integrated circuit 11 in the second embodiment is generally similar to the semiconductor integrated circuit 10 in the first embodiment, but lacks the shield lines of the first embodiment, and instead has a shielding region 30.

The shielding region 30 is a region surrounding the scan clock signal line 22 on both sides. Except for the scan clock signal line 22, signal lines carrying signals with levels that may change during normal operation are excluded from the shielding region 30. The dimensions of the shielding region 30 (the distance to which it extends from the scan clock signal line 22) are determined from, for example, the distance at which interference between different parts of the scan clock signal line and between the scan clock signal line and the other signal lines does not occur.

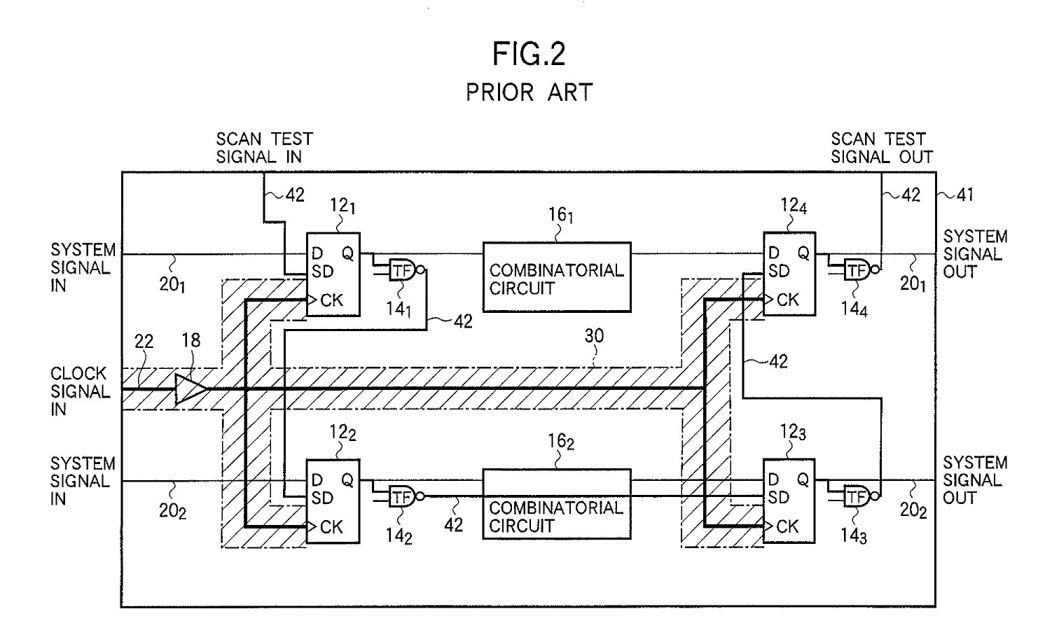

In FIG. 8, scan test signal lines 261 to 263 are partly laid out in the shielding region 30, parallel to the scan clock signal line 22, in the same signal line layer. In the conventional semiconductor integrated circuit 41 in FIG. 2, scan test signal lines 261 to 263 could only cross the shielding region 30 orthogonally, and in a different signal line layer. Consequently, scan test signal lines 261 to 263 use up fewer routing resources outside the shielding region 30 in FIG. 8 than in FIG. 2. In particular, scan test signal line 261 and scan test signal line 262 follow the scan clock signal line 22 inside the shielding region 30 for most of their length, thus using up very few routing resources outside the shielding region 30. As in the first embodiment, this conservation of routing resources reduces the cost of the semiconductor integrated circuit 11.

During normal operation the parts of scan test signal lines 261 to 263 adjacent to the scan clock signal line 22 are held at a constant potential, so they do not cause crosstalk noise. During a scan test, the clock signal on the scan clock signal line 22 has such a low frequency that crosstalk does not pose a problem. Thus the clock input terminals CK of the flip-flop circuits 121 to 124 are free of noise at all times, as in the first embodiment.

Next, a method of laying out the semiconductor integrated circuit 11 according to the second embodiment will be described. This method may be carried out with the same semiconductor integrated circuit layout apparatus 50 as in the first embodiment, shown in FIG. 6.

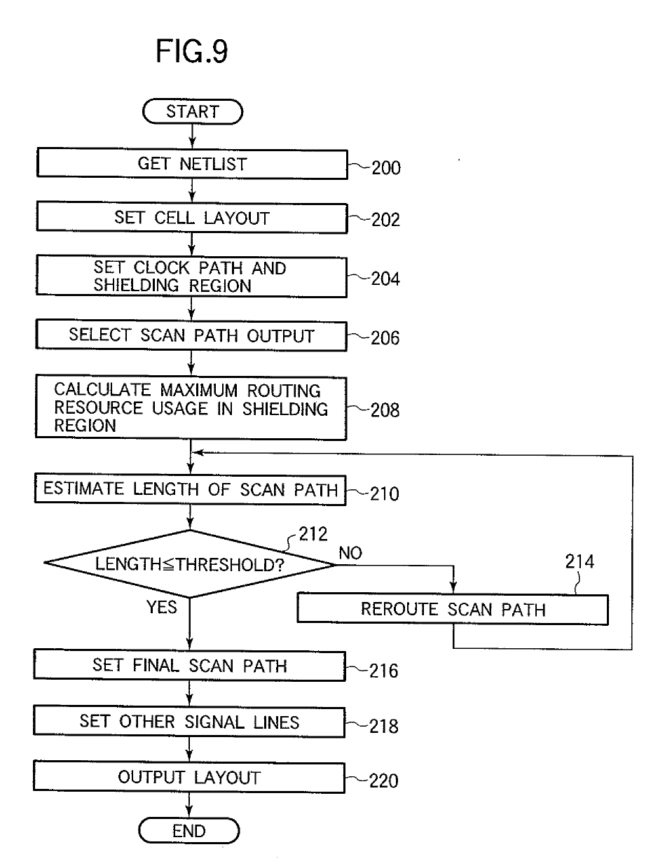

The layout process (layout method) in the second embodiment will be described with reference to FIG. 9, omitting detailed descriptions of steps that are similar to steps in the first embodiment (FIG. 7).

Steps 200 and 202 are a netlist acquisition step and a cell layout step similar to steps 100 and 102 in FIG. 7.

Step 204 is a shielding region setting step, in which the scan clock signal line 22 is routed and the shielding region 30 is defined. The shielding region 30 may be defined by specifying the distance it extends from the shielding region 30 in terms of grid units, where one grid unit is the minimum spacing between signal lines in the semiconductor integrated circuit 11. As a specific example, the shielding region 30 may be defined as the region within two grid units of the scan clock signal line 22.

The invention is not limited to this method of defining the shielding region 30. The shielding region 30 may be defined in any way that provides enough space around the scan clock signal line 22 to prevent the occurrence of crosstalk noise and other noise.

Step 206 is a scan path output selection step, in which scan path output is selected as in step 106 in FIG. 7.

Step 208 is a resource calculation step generally similar to step 108 in FIG. 7. The entire shielding region 30 is made available for the routing of scan test signal lines 261 to 263, scan test signal lines 261 to 263 are routed so as to make maximum use of the shielding region 30, and the total length of the scan test signal lines 261 to 263 within the shielding region 30 is calculated.

Steps 210, 212, and 214 are a loop similar to steps 112, 114, 116 in FIG. 7, in which the layout of scan test signal lines 261 to 263 is modified as necessary until their total length satisfies a threshold condition, the threshold being derived from the total length calculated in step 208. When the threshold condition is satisfied, the current layout of scan test signal lines 261 to 263 is made their final layout.

Step 218 is a routing step for other signal lines, similar to step 122 in FIG. 7.

Step 220 is a layout output step, generally similar to step 124 in FIG. 7, in which the graphic user interface 62 outputs the layouts obtained in steps 202, 204, 216, and 218. The layout of the semiconductor integrated circuit 11 is thereby completed and the semiconductor integrated circuit 11 may be fabricated.

As described above, according to the semiconductor integrated circuit layout method of the second embodiment (the exemplary processing flow in FIG. 9), the scan clock signal line 22 is shielded on both sides by a shielding region 30, which is then made available for routing scan test signal lines 261 to 263, which are held at a constant signal level by the NAND circuits 141 to 143 during normal operation. This enables the scan clock signal line 22 to be shielded from crosstalk noise in an economical way, conserving routing resources and reducing the chip cost of the semiconductor integrated circuit 11.

The variations of the first embodiment that were described above also apply to the second embodiment.

Following from the above description and invention summaries, it should be apparent to those of ordinary skill in the art that, while the methods and apparatuses herein described constitute exemplary embodiments of the present invention, the invention contained herein is not limited to this precise embodiment and that changes may be made to such embodiments without departing from the scope of the invention as defined by the claims. Additionally, it is to be understood that the invention is defined by the claims and it is not intended that any limitations or elements describing the exemplary embodiments set forth herein are to be incorporated into the interpretation of any claim element unless such limitation or element is explicitly stated. Likewise, it is to be understood that it is not necessary to meet any or all of the identified advantages or objects of the invention disclosed herein in order to fall within the scope of any claims, since the invention is defined by the claims and since inherent and/or unforeseen advantages of the present invention may exist even though they may not have been explicitly discussed herein.

What is claimed is:

1. A semiconductor integrated circuit comprising:
a scan test signal line;
a plurality of flip-flop circuits, each having a scan data input terminal connected to the scan test signal line, a data output terminal connected to the scan test signal line, and a clock signal input terminal, the plurality of flip-flop circuits being interconnected by the scan test signal line to form a scan chain;
a plurality of logic circuits disposed on the scan test signal line for controllably blocking scan data signals output from the data output terminals of the plurality of flip-flop circuits, thereby holding the scan test signal line at a fixed signal level;
a clock signal line for supplying a clock signal to the clock signal input terminals of the plurality of flip-flop circuits, for operating the plurality of flip-flop circuits; and
at least one shield line disposed adjacent and parallel to the clock signal line; wherein
at least one part of the scan test signal line is disposed adjacent and parallel to the clock signal line, the at least one shield line and the at least one part of the scan test signal line constituting a shielding structure that shields all parts of the clock signal line on both sides of the clock signal line.

2. A semiconductor integrated circuit comprising:
a scan test signal line;
a plurality of flip-flop circuits, each having a scan data input terminal connected to the scan test signal line, a data output terminal connected to the scan test signal line, and a clock signal input terminal, the plurality of flip-flop circuits being interconnected by the scan test signal line to form a scan chain;
a plurality of logic circuits disposed on the scan test signal line for controllably blocking scan data signals output from the data output terminals of the plurality of flip-flop circuits, thereby holding the scan test signal line at a fixed signal level;
a clock signal line for supplying a clock signal to the clock signal input terminals of the plurality of flip-flop circuits, for operating the plurality of flip-flop circuits; and
a shielding region surrounding the clock signal line to shield the clock signal line from electrical interference; wherein
at least one part of the scan test signal line is disposed in the shielding region, the at least one part of the scan test signal line being connected between at least one of the plurality of logic circuits and at least one of the data input terminals of the plurality of flip-flop circuits; and
the only signal lines included in the shielding region are the clock signal line and the at least one part of the scan test signal line.

3. The semiconductor integrated circuit of claim 2, wherein the at least one part of the scan test signal line is routed adjacent and parallel to the clock signal line in the shielding region.

4. The semiconductor integrated circuit of claim 1, wherein the scan test signal line has a length equal to or less than a threshold value determined from a length of the scan clock signal line.

5. The semiconductor integrated circuit of claim 1, wherein the plurality of logic circuits are one of NAND gates, AND gates, NOR gates, and OR gates.

6. The semiconductor integrated circuit of claim 2, wherein the scan test signal line has a length equal to or less than a threshold value determined from a length of the scan clock signal line.

7. The semiconductor integrated circuit of claim 2, wherein the plurality of logic circuits are one of NAND gates, AND gates, NOR gates, and OR gates.

8. A method of laying out the semiconductor integrated circuit of claim 1, comprising:
obtaining a netlist;
laying out the plurality of flip-flop circuits according to the netlist;
laying out the plurality of logic circuits and the clock signal line according to the netlist, after laying out the plurality of flip-flop circuits; and
laying out the scan test signal line and the at least one shield line after laying out the plurality of logic circuits and the clock signal line.

9. The method of claim 8, further comprising:
determining a length of the clock signal line after laying out the clock signal line;
determining a threshold value from the length of the clock signal line; and
iterating the laying out of the scan test signal line and the laying out of the at least one shield line until the scan test signal line has a length equal to or less than the threshold value.

10. The method of claim 9, wherein said iterating the laying out of the scan test signal line further comprises reordering the scan chain.

11. A machine-readable tangible medium storing instructions executable by a computing device to carry out the method of claim 8.

12. The machine-readable tangible medium of claim 11, wherein the instructions include:
instructions for determining a length of the clock signal line after laying out the clock signal line;
instructions for determining a threshold value from the length of the clock signal line; and
instructions for iterating the laying out of the scan test signal line and the laying out of the at least one shield line until the scan test signal line has a length equal to or less than the threshold value.

13. A method of laying out the semiconductor integrated circuit of claim 2, comprising:
obtaining a netlist;
laying out the plurality of flip-flop circuits according to the netlist;
laying out the plurality of logic circuits and the clock signal line according to the netlist, after laying out the plurality of flip-flop circuits;
laying out the shielding region after laying out the clock signal line; and
laying out the scan test signal line after laying out the shielding region.

14. The method of claim 13, further comprising:
determining a length of the clock signal line after laying out the clock signal line;
determining a threshold value from the length of the clock signal line; and
iterating the laying out of the scan test signal line until the scan test signal line has a length equal to or less than the threshold value.

15. The method of claim 14, wherein said iterating the laying out of the scan test signal line further comprises reordering the scan chain.

16. A machine-readable tangible medium storing instructions executable by a computing device to carry out the method of claim 13.

17. The machine-readable tangible medium of claim 16, wherein the instructions include:
instructions for determining a length of the clock signal line after laying out the clock signal line;
instructions for determining a threshold value from the length of the clock signal line; and
instructions for iterating the laying out of the scan test signal line until the scan test signal line has a length equal to or less than the threshold value.
